(19) United States
(12) Patent Application Publication
(10) Pub. No.: US 2008/0106304 A1
(43) Pub. Date: May 8, 2008

(54) SEMICONDUCTOR CIRCUITS USING VERTICAL BIPOLAR JUNCTION TRANSISTOR

(76) Inventors: Hyun-Won Mun, Yongin-si (KR); Il-Ku Nam, Anyang-si (KR)

Correspondence Address: Frank Chau, Esq.;F. CHAU & ASSOCIATES, LLC, 130 Woodbury Road, Woodbury, NY, 11797, US

(21) Appl. No.: 11/560,452

(22) Filed: Nov. 16, 2006

(30) Foreign Application Priority Data
Jan. 20, 2006 (KR) 10-2006-0006477

(51) Int. Cl. G01R 19/00

(52) U.S. Cl. 327/51

(57) ABSTRACT

An amplifier circuit includes: an amplification transistor, which is connected to an input node and an output node, amplifying an input signal and generating an output signal; and a load connected between the output node and a predetermined power supply node, wherein the amplification transistor is a vertical bipolar junction transistor. A variable gain amplifier circuit includes: a voltage converter converting a control voltage and outputting a converted control voltage; and an amplification transistor receiving the converted control signal from the voltage converter and amplifying an input signal to output an output signal whose gain is proportional to the control voltage, wherein the amplification transistor is a vertical bipolar junction transistor. A single pole log-domain circuit includes: a first transistor receiving an input current; a second transistor having a base terminal connected to a base terminal of the first transistor; a third transistor having an emitter terminal connected to an emitter terminal of the second transistor; and a fourth transistor having a base terminal connected to a base terminal of the third transistor, wherein each of the first through fourth transistors is a vertical BJT.

### CROSS-REFERENCE TO RELATED PATENT APPLICATION

This application claims priority to Korean Patent Application No. 10-2006-0006477, filed on Jan. 20, 2006, the disclosure of which is herein incorporated by reference in its entirety.

### BACKGROUND OF THE INVENTION

1. Technical Field

The present disclosure relates to semiconductor circuits and, more particularly, to semiconductor circuits using a vertical bipolar junction transistor (BJT).

2. Discussion of Related Art

Generally, a bipolar junction transistor (BJT) has better junction characteristics than a metal-oxide semiconductor field effect transistor (MOSFET). Some circuits require BJT operating characteristics to perform a particular function. It can be necessary to implement both a MOS device and a BJT device in a single process. However, a bipolar complementary metal-oxide semiconductor (BiCMOS) process, which refers to the integration of CMOS and BJT technology into a single device, is more complex and more expensive than a CMOS process.

Accordingly, it is difficult and uneconomical to implement a BJT device using a standard CMOS process. For this reason, a MOSFET device operating in the sub-threshold region is used in a CMOS process to design a circuit to achieve the operating characteristics of a BJT. The sub-threshold region is also referred to as the weak inversion region. With respect to the characteristics of MOS devices, Equation (1) holds in general.

$${I}_{D} = K \frac{{x}^{2}}{1 + θ x} \\ x = 2 {ηφ}_{1} 1 n ( 1 + {e}^{\frac{{V}_{gs} - {V}_{th}}{2 {ηφ}_{1}}} ) , \qquad ( 1 )$$

where Vₜₕ is a threshold, φₜ is a thermal voltage (=kT/q), K=_{μo}CoxW/(2L), θ is a normal field mobility degradation factor, and ηis a slope factor.

Equation (2) holds in the sub-threshold region:

$${V}_{gs} \leq {V}_{th} \\ x = 2 η {φ}_{1} {e}^{\frac{{V}_{gs} - {V}_{th}}{2 η {φ}_{1}}} \\ I = {K ( 2 η {φ}_{1} )}^{2} {e}^{\frac{{V}_{gs} - {V}_{th}}{η {φ}_{1}}} . \qquad ( 2 )$$

As can be seen from Equation (2), the current I and the voltage V_{gs} of a transistor have an exponential relationship in the sub-threshold region. Accordingly, the MOSFET device operating in the sub-threshold region has the operating characteristics of a BJT. Circuits using a MOSFET operating in the sub-threshold region to obtain the operating characteristics of a BJT are known.

However, MOSFET devices operating in the sub-threshold region operate below the threshold voltage Vₜₕ of a transistor and, thus, are limited in operating voltage. As a result, the dynamic range of current exponentially proportional to voltage is reduced. Moreover, the current is so small that current drivability decreases.

In addition, MOSFET devices are very sensitive to changes in process variables such as temperature, pressure, and voltage. To drive MOSFET devices in the sub-threshold region, the bias conditions should be precisely controlled. When the process variables change, MOSFET devices may deviate from the sub-threshold region or may not show expected characteristics, and repeatability or reliability may be decreased.

Moreover, MOSFET devices have limited high-frequency performance. High-frequency performance is usually proportional to current. However, the current of MOSFET devices operating in the sub-threshold region is so small that it is relatively difficult to drive MOSFET devices at a high frequency when operating in the sub-threshold region.

Technology capable of replacing MOSFET devices operating in a sub-threshold region is needed for circuits implemented by a CMOS process to achieve BJT operating characteristics.

### SUMMARY OF THE INVENTION

According to an exemplary embodiment of the present invention, there is provided an amplifier circuit including: an amplification transistor, connected to an input node and an output node, amplifying an input signal and generating an output signal; and a load connected between the output node and a predetermined power supply node, wherein the amplification transistor is a vertical BJT.

According to an exemplary embodiment of the present invention, there is provided a variable gain amplifier circuit including: a voltage converter converting a control voltage and outputting a converted control voltage, and an amplification transistor receiving the converted control signal from the voltage converter and amplifying an input signal to output an output signal whose gain is proportional to the control voltage, wherein the amplification transistor is a vertical BJT.

According to an exemplary embodiment of the present invention, there is provided a single pole log-domain circuit including: a first transistor receiving an input current; a second transistor having a base terminal connected to a base terminal of the first transistor; a third transistor having an emitter terminal connected to an emitter terminal of the second transistor; and a fourth transistor having a base terminal connected to a base terminal of the third transistor, wherein each of the first through fourth transistors is a vertical BJT.

According to an exemplary embodiment of the present invention, there is provided a method of controlling a gain of an amplifier circuit. The method includes: forming an amplification transistor using a deep N-well complementary metal-oxide semiconductor (CMOS) process, the amplification transistor being a vertical bipolar junction transistor; converting a control voltage and outputting a converted control voltage using a voltage controller; and receiving the converted control signal from the voltage converter and amplifying an input signal to output an output signal whose gain is proportional to the control voltage using the amplification transistor.

According to an exemplary embodiment of the present invention, there is provided a method of implementing a single pole log-domain circuit. The method includes: connecting a base terminal of a second transistor to a base terminal of a first transistor; connecting an emitter terminal of a third transistor to an emitter terminal of the second transistor; and connecting a base terminal of a fourth transistor to a base terminal of the third transistor, wherein each of the first through fourth transistors is a vertical bipolar junction transistor.

### BRIEF DESCRIPTION OF THE DRAWINGS

The present invention will become readily apparent to those of ordinary skill in the art when descriptions of exemplary embodiments thereof are read with reference to the accompanying drawings.

FIG. 1 is a cross-sectional view of a vertical NPN bipolar junction transistor (BJT) implemented using a deep N-well complementary metal-oxide semiconductor (CMOS) process, according to an exemplary embodiment of the present invention.

FIG. 2 is a cross-sectional view of a vertical NPN BJT implemented using a deep N-well CMOS process, according to an exemplary embodiment of the present invention.

FIG. 3 is a diagram of an amplifier circuit according to an exemplary embodiment of the present invention.

FIG. 4 is a diagram of a variable gain amplifier circuit according to an exemplary embodiment of the present invention.

FIG. 5 is a graph of control voltage versus gain of the variable gain amplifier circuit illustrated in FIG. 4.

FIG. 6 is a diagram of a single pole log-domain circuit according to an exemplary embodiment of the present invention.

### DESCRIPTION OF EXEMPLARY EMBODIMENTS

Hereinafter, exemplary embodiments of the present invention will be described in detail with reference to the accompanying drawings. Like reference numerals refer to similar or identical elements throughout the description of the figures.

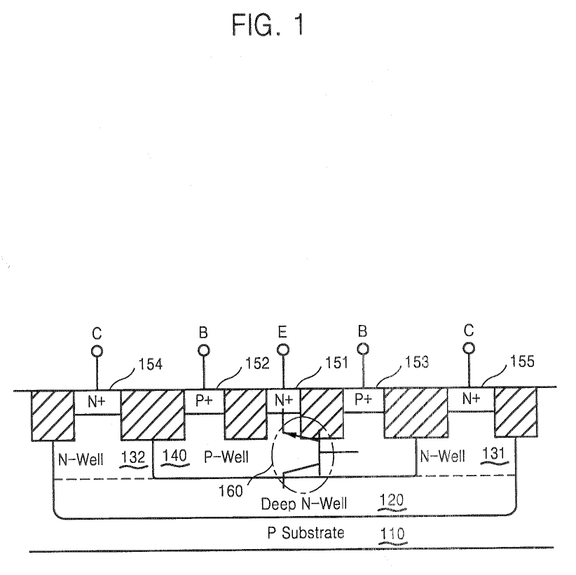

FIG. 1 is a cross-sectional view of a vertical NPN bipolar junction transistor (BJT) 160 implemented using a deep N-well complementary metal-oxide semiconductor (CMOS) process, according to an exemplary embodiment of the present invention. Referring to FIG. 1, a deep N-well 120 is formed on a P substrate 110. N-wells 131 and 132 and a P-well 140 are formed on the deep N-well 120. N+ or P+ ions are implanted or diffused into each of predetermined regions in the N-wells 131 and 132 and the P-well 140, forming base contact regions 152 and 153, collector contact regions 154 and 155, and an emitter contact region 151. For example, an N+region 151 in the P-well 140 forms an emitter; the P-well 140 and P+contacts 152 and 153 form a base; and the deep N-well 120, the N-wells 131 and 132, and N+regions 154 and 155 form a collector.

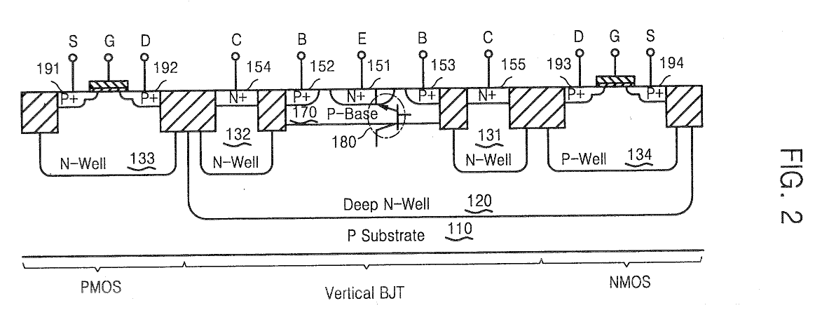

FIG. 2 is a cross-sectional view of a vertical NPN BJT 180 implemented using a deep N-well CMOS process, according to an exemplary embodiment of the present invention. Referring to FIG. 2, a P-base process is added to the deep N-well CMOS process illustrated in FIG. 1.

In addition, a positive-channel MOS (PMOS) transistor and a negative-channel MOS (NMOS), which are implemented using a deep N-well CMOS process, are illustrated in FIG. 2. An N-well 133 forms a gate, and P+regions (i.e., P+ ion implanted or diffused regions) 191 and 192 in the N-well 133 form a source and drain, forming a PMOS transistor. A P-well 134 forms a gate, and N+ regions 193 and 194 in the P-well 134 form a source and drain, forming an NMOS transistor. PMOS transistors and NMOS transistors, which are implemented using a deep N-well CMOS process, are welt known in the art. Thus, further descriptions thereof will be omitted in the interests of clarity and simplicity.

When the P-base process is performed, the N-wells 131 and 132 and a P-base 170 are formed on the deep N-well 120, as illustrated in FIG. 2. N+ or P+ ions are implanted or diffused into each of predetermined regions in the N-wells 131 and 132 and the P-base 170, forming the base contact regions 152 and 153: the collector contact regions 154 and 155, and the emitter contact region 151. For example, the N+region 151 in the P-base 170 forms an emitter; the P-base 170 and the P+ contacts 152 and 153 form a base; and the deep N-well 120, the N-wells 131 and 132, and N+ regions 154 and 155 form a collector.

The current gain (β) of a BJT is related to the base width such that when the base width decreases, the current gain increases. The P-well 140 is relatively thick in the vertical BJT 160 of FIG. 1, and the current gain is low. The P-base 170 is relatively thin in the vertical BJT 180 of FIG. 2, and the current gain has higher performance characteristics than in the vertical BJT 160 illustrated in FIG. 1. That is, since the depth of the P-base 170 is less than that of the P-well 140, the performance of the vertical BJT 180 illustrated in FIG. 2 may be better than that of the vertical BJT 160 illustrated in FIG. 1.

According to an exemplary embodiment of the present invention, instead of a metal-oxide semiconductor field effect transistor (MOSFET) operating in a sub-threshold region, a vertical BJT implemented using a deep N-well CMOS process is used in an amplifier circuit and a single pole log-domain circuit to improve the performance of semiconductor circuits requiring BJT operating characteristics.

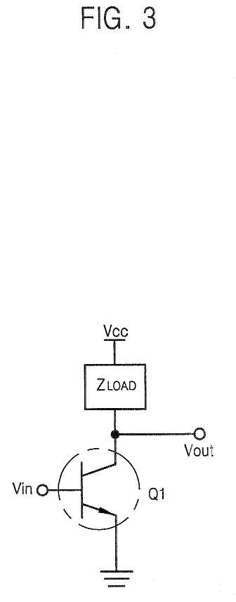

FIG. 3 is a diagram of an amplifier circuit according to an exemplary embodiment of the present invention. Referring to FIG. 3, the amplifier circuit includes a transistor Q1 and a load Z_{LOAD}. The transistor Q1 is a vertical BJT implemented using a deep N-well CMOS process. The transistor Q1 amplifies an input signal Vin and generates an amplified output signal Vout. The transistor Q1 may include a base terminal receiving the input signal Vin, an emitter terminal which is electrically connected to a predetermined node (e.g., a ground node), and a collector terminal which is electrically connected to an output node. The load Z_{LOAD} is connected between the output node and a supply voltage (Vcc) node.

When an amplifier circuit is implemented using a vertical BJT implemented using a deep N-well CMOS process according to an exemplary embodiment of the present invention, as illustrated in FIG. 3, a current/voltage dynamic range is wide and current drivability also increases as compared to a conventional amplifier circuit using a MOSFET operating in a sub-threshold region. In addition, the amplifier circuit according to an exemplary embodiment of the present invention is less sensitive to process variations, and circuit reliability and high-frequency characteristics may be improved.

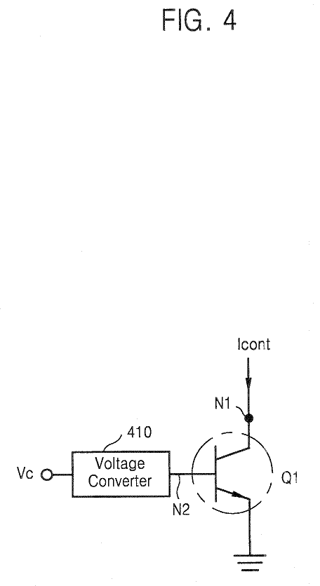

FIG. 4 is a diagram of a variable gain amplifier circuit according to an exemplary embodiment of the present invention. Referring to FIG. 4, the variable gain amplifier circuit includes a transistor Q1 and a voltage converter 410.

The transistor Q1 is, as described above, a vertical BJT implemented using a deep N-well CMOS process. For example, the transistor Q1 may include a base terminal which is electrically connected to the voltage converter 410, an emitter terminal which is electrically connected to a predetermined node (here, a ground node), and a collector terminal which is electrically connected to an output node N1. The vertical BJT, here, the transistor Q1, amplifies the base current and generates an amplified output current signal Icont.

The variable gain amplifier circuit illustrated in FIG. 4 may further include an output load (not shown) between the output node N1 and a predetermined power supply. In this case, an amplified voltage signal can be obtained from the output node N1. The gain of the variable gain amplifier circuit is controlled based on a control voltage Vc.

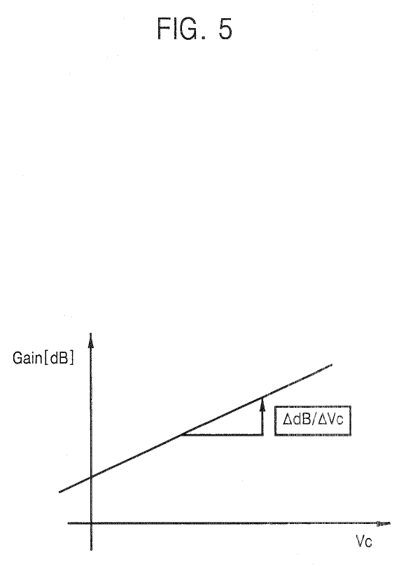

FIG. 5 is a graph of the control voltage Vc versus the gain of the variable gain amplifier circuit illustrated in FIG. 4. Referring to FIG. 5, the gain of the variable gain amplifier circuit increases in proportional to the control voltage Vc. Accordingly, the gain of the variable gain amplifier circuit can be adjusted by controlling the control voltage Vc.

The voltage converter 410 illustrated in FIG. 4 converts the control voltage Vc according to a predetermined function. A converted control voltage is applied to a base terminal N2 of the vertical BJT Q1 and the gain of the vertical BJT Q1 is determined by the converted control voltage.

A variable gain amplifier circuit according to an exemplary embodiment of the present invention as illustrated in FIG. 4 uses a vertical BJT implemented using a deep N-welt CMOS process and may have improved current drivability, circuit reliability, and high-frequency characteristics as compared to a conventional variable gain amplifier circuit that uses a MOSFET operating in a sub-threshold region.

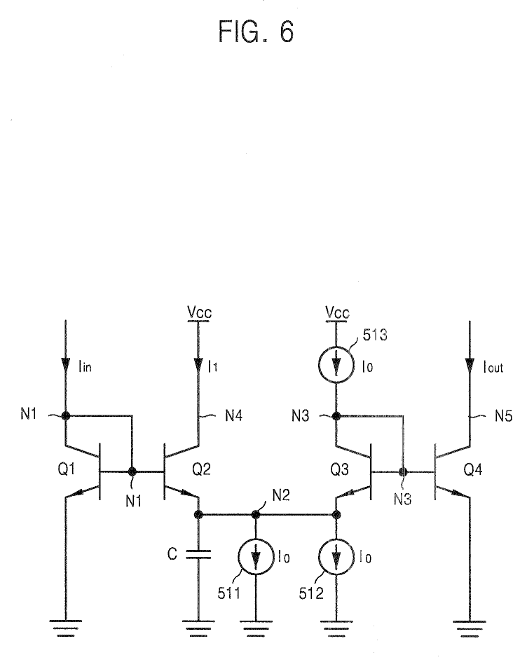

FIG. 6 is a diagram of a single pole log-domain circuit according to an exemplary embodiment of the present invention. Referring to FIG. 6, the single pole log-domain circuit includes first through fourth transistors Q1, Q2, Q3, and Q4; first through third current sources 511, 512, and 513; and a capacitor C.

Each of the first through fourth transistors Q1, Q2, Q3, and Q4 shown in FIG. 6 is, as described above, a vertical BJT implemented using a deep N-well CMOS process. Base terminals N1 of the first and second transistors Q1 and Q2 are electrically connected to each other, and base terminals N3 of the third and fourth transistors Q3 and Q4 are electrically connected to each other. Emitter terminals of the respective second and third transistors Q2 and Q3 are electrically connected to a common emitter node N2. The capacitor C and the first and second current sources 511 and 512 are connected in parallel between the common emitter node N2 and a ground node. The third current source 513 is connected between a power supply Vcc and the base terminals N3 of the third and fourth transistors Q3 and Q4. The first through third current sources 511, 512, and 513 supply a predetermined current I₀.

When an input current signal Iᵢₙ is input to the first transistor Q1, an output current signal Iₒᵤₜ can be determined by Equation (3):

$$\text{indicates text missing or illegible when filed}$$

where V_{CM} is a voltage of the common emitter node N2 and V_{T} is a thermal voltage.

The transfer function of the circuit illustrated in FIG. 6 can be expressed by Equation (4):

$$G ( s ) = \frac{{I}_{out} ( s )}{{I}_{in} ( s )} = \frac{1}{s τ + 1} , \\ where \\ {f}_{0} = {f}_{3 dB} = \frac{1}{2 πτ} = \frac{2}{2 π} \frac{{I}_{0}}{{CV}_{T}} \\ and {f}_{0} is a 3 dB cutoff frequency . \qquad ( 4 )$$

The circuit illustrated in FIG. 6 may serve as a first-order low pass filter or integrator. A pair of transistors having the same structure as the first and second transistors Q1 and Q2 may be inserted between a node N1 and the power supply Vcc and between a node N4 and the power supply Vcc, respectively, and a pair of transistors having the same structure as the third and fourth transistors Q3 and Q4 may be inserted between a node N3 and the power supply Vcc and between a node N5 and the power supply Vcc, respectively, realizing a cascode circuit.

Each of the transistors included in a single pole log-domain circuit according to an exemplary embodiment of the present invention shown in FIG. 6 comprises a vertical BJT implemented using a deep N-well CMOS process, which may provide improved current drivability, circuit reliability, and high-frequency characteristics as compared to a conventional single pole log-domain circuit that uses a MOSFET operating in a sub-threshold region.

A vertical BJT device according to an exemplary embodiment of the present invention may be less sensitive to changes in process variables, e.g., temperature, pressure, and voltage, providing greater repeatability and reliability with improved high-frequency performance.

Although exemplary embodiments of the present invention have been described in detail with reference the accompanying drawings for the purpose of illustration, it is to be understood that the inventive processes and apparatus should not be construed as limited thereby. It will be readily apparent to those of reasonable skill in the art that various modifications to the foregoing exemplary embodiments may be made without departing from the scope of the invention as defined by the appended claims, with equivalents of the claims to be included therein.

What is claimed is:

1. An amplifier circuit comprising:
an amplification transistor, connected to an input node and an output node, amplifying an input signal and generating an output signal; and
a load connected between the output node and a predetermined power supply node,
wherein the amplification transistor is a vertical bipolar junction transistor implemented using a deep N-well complementary metal-oxide semiconductor (CMOS) process.

2. The amplifier circuit of claim 1, wherein the amplification transistor is implemented using a deep N-well CMOS process and a P-base process.

3. The amplifier circuit of claim 1, wherein the amplification transistor is an NPN type vertical transistor comprising:
a collector formed by a deep N-well region, an N-well region and an N+region, wherein the N-well region and the N+region are disposed on the deep N-well region;
a base formed by a P-well region and a P+region, which are disposed on the deep N-well region; and
an emitter formed by an N+region disposed on the P-well region.

4. A variable gain amplifier circuit comprising:
a voltage converter converting a control voltage and outputting a converted control voltage; and
an amplification transistor receiving the converted control signal from the voltage converter and amplifying an input signal to output an output signal whose gain is proportional to the control voltage,
wherein the amplification transistor is a vertical bipolar junction transistor implemented using a deep N-well complementary metal-oxide semiconductor (CMOS) process.

5. The variable gain amplifier circuit of claim 4, wherein the amplification transistor is implemented using a deep N-well CMOS process and a P-base process.

6. The variable gain amplifier circuit of claim 4 wherein the amplification transistor is an NPN type vertical transistor comprising:
a collector formed by a deep N-well region, an N-well region and an N+region, wherein the N-well region and the N+region are disposed on the deep N-well region; a base formed by a P-well region and a P+region, which are disposed on the deep N-well region; and an emitter formed by an N+region disposed on the P-well region.

7. A single pole log-domain circuit comprising:
a first transistor receiving an input current;
a second transistor having a base terminal connected to a base terminal of the first transistor;
a third transistor having an emitter terminal connected to an emitter terminal of the second transistor; and
a fourth transistor having a base terminal connected to a base terminal of the third transistor,
wherein each of the first through fourth transistors is a vertical bipolar junction transistor implemented using a deep N-well complementary metal-oxide semiconductor (CMOS) process.

8. The single pole log-domain circuit of claim 7, wherein the first through fourth transistors are implemented using the deep N-well CMOS process and a P-base process.

9. The single pole log-domain circuit of claim 7, wherein a transfer function G(s) between the input current and a current of the fourth transistor is defined as:
$$G ( s ) = \frac{{I}_{out} ( s )}{{I}_{in} ( s )} = \frac{1}{s τ + 1} ,$$
where Iᵢₙ is the input current and Iₒᵤₜ is the current of the fourth transistor.

10. A method of controlling a gain of an amplifier circuit, comprising:
forming an amplification transistor using a deep N-well complementary metal-oxide semiconductor (CMOS) process, the amplification transistor being a vertical bipolar junction transistor;
converting a control voltage and outputting a converted control voltage using a voltage controller; and
receiving the converted control signal from the voltage converter and amplifying an input signal to output an output signal whose gain is proportional to the control voltage using the amplification transistor implemented using a deep N-well complementary metal-oxide semiconductor (CMOS) process.

11. A method of implementing a single pole log-domain circuit, comprising:
connecting a base terminal of a second transistor to a base terminal of a first transistor;
connecting an emitter terminal of a third transistor to an emitter terminal of the second transistor; and
connecting a base terminal of a fourth transistor to a base terminal of the third transistor,
wherein each of the first through fourth transistors is a vertical bipolar junction transistor implemented using a deep N-well complementary metal-oxide semiconductor (CMOS) process.

12. The method of implementing a single pole log-domain circuit of claim 11, wherein each of the first through fourth transistors is implemented using a deep N-well CMOS process and a P-base process.
